(19) United States
(12) Patent Application Publication
(10) Pub. No.: US 2003/0001110 A1
(43) Pub. Date: Jan. 2, 2003

(54) System and method for amplifying an angle of divergence of a scanned ion beam

(76) Inventors: Harald Enge, Sherborn, MA (US); Donald W. Berrian, Topsfield, MA (US)

Correspondence Address: LATHROP & GAGE LC, 4845 PEARL EAST CIRCLE, SUITE 300, BOULDER, CO, 80301, US

(21) Appl. No.: 10/071,443

(22) Filed: Feb. 6, 2002

Related U.S. Application Data
(60) Provisional application No. 60/266,672, filed on Feb. 6, 2001.
(60) Provisional application No. 60/258,844, filed on Dec. 28, 2000.

(51) Int. Cl. H01J 37/147; H01J 37/317

(52) U.S. Cl. 250/492.21; 250/398; 250/396 ML

(57) ABSTRACT

A system for amplifying a scan of an ion beam is provided. Examples of the system include a magnetic scanner and a beam amplifier in combination. The magnetic scanner is configured to scan the ion beam in a single plane. The beam amplifier is configured to receive the ion beam from the magnetic scanner, amplify a divergence of the ion beam, and focus the ion beam in the single plane.

### RELATED APPLICATIONS

This application claims benefit to provisional application serial No. 60/266,672, filed Feb. 6, 2001, and is a continuation-in-part of PCT application entitled “Ion Beam Collimator System” filed Dec. 28, 2001 designating the United States; which claims priority to the provisional serial No. 60/258,844 filed Dec. 28, 2000, each of which is hereby incoroporated by reference to the extent as though fully replicated herein.

### BACKGROUND OF THE INVENTION

1. Field of the Invention

This invention relates to the field of semiconductor manufacturing and, in particular, to ion implanting systems and operational methods.

2. Description of the Related Art

Semiconductor devices may be produced by implanting ions into a semiconductor substrate through a use of an ion implantation device. The ion implantation device extracts an ion beam from an ion source and accelerates it with electric field. The ion beam is transported through a vacuum to an analyzer. The analyzer typically consists of a dipole magnet that produces a magnetic field to discriminately select ions for implantation. Once the ion beam passes through the analyzer, the ion beam enters a scanner, which deflects or scans the ion beam over predetermined paths in a single plane. After being deflected, particles within the ion beam may be further accelerated before striking a target, such as a silicon wafer that forms a semiconductor substrate.

Deflected paths of the ion beam cause the ion beam to impinge the target at varying angles. Varying angles of ion beam paths create non-uniform implantations of ions into a target with associated device performance problems. An electrostatic or magnetic lens collimates the deflected paths to avoid non-uniform implantations as described in U.S. Pat. No. 4,922,106 issued to Berrian et al., and incorporated herein by reference.

The scanner deflects the ion beam using either a time varying electric field or a time varying magnetic field. Electric fields are used particularly for fast scanning since the electric field required to deflect an ion beam has less stored energy than the corresponding magnetic field. Therefore, electric field scanners require less power than magnetic field scanners. However, electric scanners do not function as well as magnetic scanners when operating on high current ion beams at low energies.

The ion beam generates and attracts a cloud of electrons when traveling through parts of the system that do not have strong electric fields. The electrons neutralize the charge in the ion beam and prevent ions from repelling one another. The field in an electric scanner removes the electrons and causes the ions to repel one another. The repelled ions cause the ion beam to expand.

At high ion beam currents and low energies, the ion beam will expand such that the ion beam collides with walls of a vacuum chamber. Therefore, the ion beam current is kept lower than desired. Increased wafer sizes demand higher ion beam currents. Reductions in ion implant depths require lower ion beam energies. Both increased wafer sizes and reductions in ion implant depths make electrical scanning undesirable for ion implantation devices.

Magnetic scan systems exist as described in U.S. Pat. No. 5,481,116 issued to Glavish, et al., and incorporated herein by reference. However, such magnetic scan systems require high power amplifiers. These magnetic scan systems also require magnetic structures enclosed in the vacuum chamber to achieve large angles of deflection. High power amplifiers and vacuum enclosed magnetic structures increase development costs and operating costs of the ion implantation device.

### SUMMARY OF THE SOLUTION

The invention helps solve the above problem and advances the art by providing a system for amplifying a scan of an ion beam in a manner that provides exceptional beam uniformity.

Examples of the system include a magnetic scanner and a beam amplifier. The magnetic scanner is configured to scan the ion beam in a single plane. The beam amplifier is configured to receive the ion beam from the magnetic scanner, to amplify a divergence of the ion beam, and to focus the ion beam in the single plane.

In some embodiments, the system includes a magnetic lens configured to receive the ion beam from the beam amplifier and focus the ion beam. For example, the magnetic lens may include a quadrupole magnet. The magnetic lens may be programmable to vary a magnetic field within the magnetic lens, and the magnetic lens may focus the ion beam into collimated paths.

In some embodiments, the system includes an analyzer configured to select predetermined ions from the ion beam. For example, the analyzer may include a momentum-analyzing magnet and the momentum-analyzing magnet may include a dipole magnet.

Other features of the system may include an ion source configured to generate the ion beam, a vacuum chamber configured to transport the ion beam, and an accelerator configured to accelerate ions from the ion beam to a target to produce the desired implant energy of the ions on the target. In some embodiments, the beam amplifier includes a magnetic lens configured to amplify the divergence of the ion beam and focus the ion beam by the operation of a quadrupole magnet. The quadrupole magnet can be programmable to vary a magnetic field within the magnetic lens.

Advantages of the following embodiments include reducing a size of a magnet within a magnetic scanner, which reduces a size and a cost of the magnetic scanner. Other advantages include an improved beam divergence to provide a single plane beam. Other advantages include improved ion implantation into the target. Still, other advantages include creating large programmable scan angles of deflection paths for ion implantation. And still other advantages include introducing a divergence angle amplifier that reduces the power required to drive the magnetic scanner.

### DESCRIPTION OF THE DRAWINGS

FIG. 1A illustrates an ion implanter system in the prior art;

FIG. 1B illustrates an overhead view of the ion beam from the ion implanter system in the prior art of FIG. 1A;

FIG. 1C illustrates a three dimensional view of the ion beam from the ion implanter system in the prior art of FIG. 1A;

FIG. 2 illustrates one system of the invention for amplifying a scan of an ion beam;

FIG. 3A illustrates one ion implanter system of the invention;

FIG. 3B illustrates an overhead view of the ion beam from the ion implanter system of FIG. 3A;

FIG. 3C illustrates a three dimensional view of the ion beam from the ion implanter system of FIG. 3A;

FIG. 4 illustrates one magnetic lens of the invention;

FIG. 5 illustrates an operation of one magnetic lens; and

FIG. 6 illustrates an operation of another magnetic lens.

The same reference number represents the same element on all drawings.

### DETAILED DESCRIPTION OF THE DRAWINGS

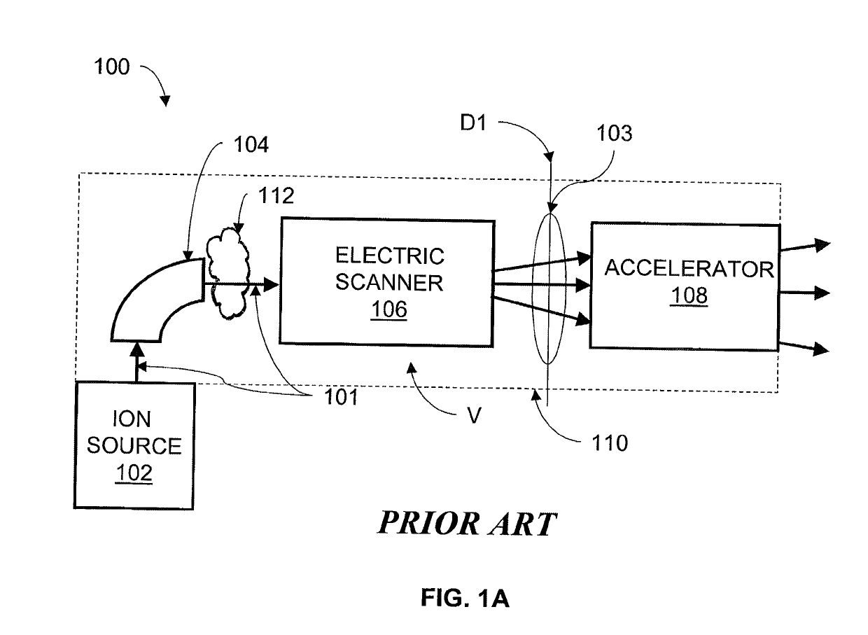

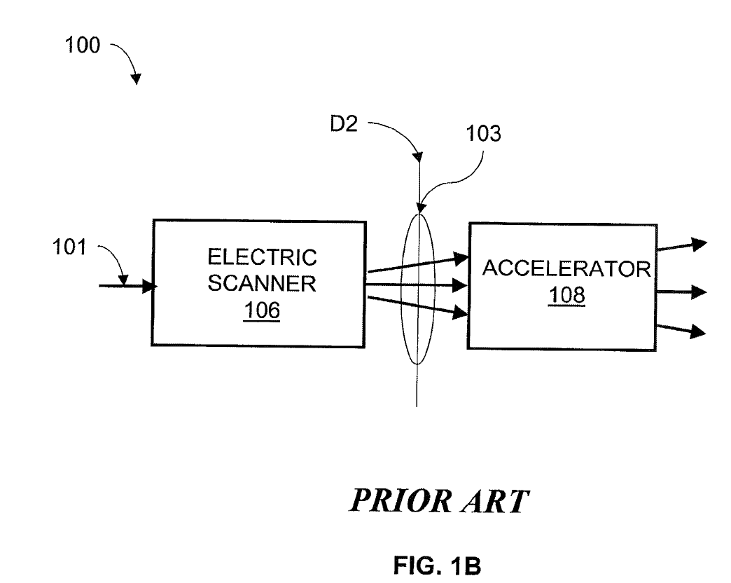

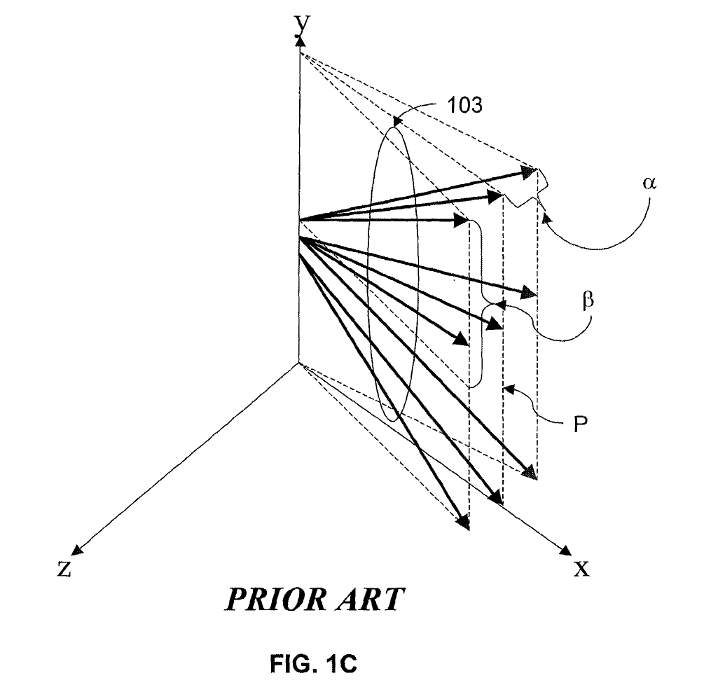

Prior Art Ion Implanter System—FIGS. 1A, 1B, and 1C

FIG. 1A illustrates ion implanter system 100 in the prior art. Ion implanter system 100 includes ion source 102, analyzer 104, electric scanner 106, and accelerator 108. Ion source 102 generates ion beam 101. Analyzer 104 receives ion beam 101 from ion source 102. Analyzer 104 selects predetermined ions from ion beam 101. Electric scanner 106 scans ion beam 101 in diverging paths, such as paths 103 located in plane D1. Accelerator 108 either accelerates or decelerates ions from ion beam 101 to a predetermined energy level before striking a target.

Vacuum V in vacuum chamber 110 is used to transport ion beam 101 from ion source 102 through accelerator 108. Those skilled in the art will appreciate various configurations of vacuum chamber 110. As vacuum V is not a perfect vacuum, ion beam 301 ionizes other gases in vacuum V. Positive ions are produced and are repulsed by ion beam 101. Electrons form charged cloud 112 that surrounds ion beam 101, but the electrons do not combine with particles of ion beam 101. The negatively charged electrons are attracted to the positively charged ions and form a cloud 112 through which the ions travel. Charged cloud 112 tends to neutralize ion beam 101.

Electric scanner 106 scans ion beam 101 to create paths 103. An electric field generated by electric scanner 106 can pull neutralizing electrons from charged cloud 112, which, with growth, increasingly creates divergence in ion beam 101. Excessive divergence in other planes causes ion beam 101 to collide with walls of vacuum chamber 110. Low-energy ion implanters with high ion beam currents are particularly sensitive to excessive divergence in other planes.

FIG. 1B illustrates an overhead view of ion beam 101 of ion implanter system 100 in the prior art. The overhead view of ion implanter system 100 shows unintentional divergence of ion beam 101 in plane D2. Plane D2 is perpendicular to plane D1 discussed above. Although plane D2 is shown as perpendicular to plane D1, divergence of ion beam 101 in planes other than D1, which may or may not be perpendicular to plane D1, can also exist.

FIG. 1C illustrates a three-dimensional view of paths 103 from ion beam 101 after being scanned by electric scanner 106 in the prior art. The three-dimensional view shows intentional divergence of paths 103 generated by scanner 106 in the X-Y plane. The three-dimensional view also shows unintentional divergence of ion beam 101 in planes that vary by an angle a of divergence. Unintentional divergence of ion beam 101 can also occur in planes other than the X-Y plane. Excessive divergence of ion beam 101 in other planes creates non-uniform ion implantations into a target. Angle a illustrates an angle of divergence in which the ion beam unintentionally diverges from the X-Y plane. Angle β illustrates an angle of divergence in which the ion beam unintentionally diverges from a center path of paths 103.

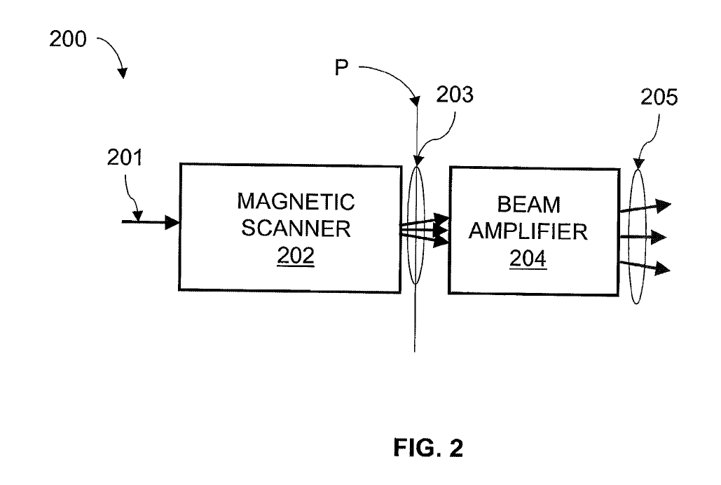

Ion Beam Amplifying System—FIG. 2

FIG. 2 illustrates one system 200 for amplifying a scan of an ion beam in accordance with the invention. System 200 includes magnetic scanner 202 and beam amplifier 204 which, in combination, overcome the problems of beam divergence that have been described in reference to the prior art. Magnetic scanner 202 is configured to scan ion beam 201 in a substantially single plane P. Magnetic scanner 202 can include magnets.

Beam amplifier 204 is configured to receive ion beam 201 from magnetic scanner 202, to amplify a divergence of ion beam 201, and to focus ion beam 201 in the substantially single plane P. Beam amplifier 204 can include magnets and/or electronic circuitry.

An ion beam includes any source of positive or negative ions, and these are usually generated from neutral atoms. An example of an ion beam can include Boron ions with an energy of 50 KeV and beam current of 1.5 milliamps. Divergence of ion beam 201 is shown in paths 203 and 205. Magnetic scanner 202 diverges paths 203 of ion beam 201. Beam amplifier 204 amplifies divergence of paths 203 from magnetic scanner 202. The amplified divergence is shown as paths 205. The magnitude of divergence for paths 203 and paths 205 is not to scale. Substantially single plane P may, for example, define a surface such that a straight line in the general direction of paths 203 and 205 joining two of its points lies wholly with the surface.

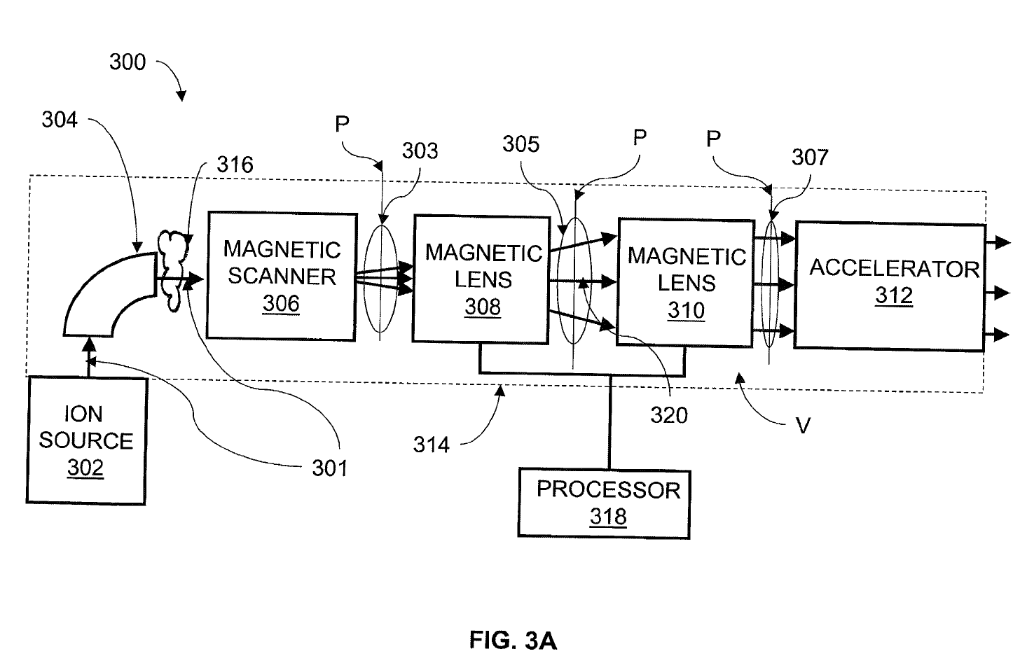

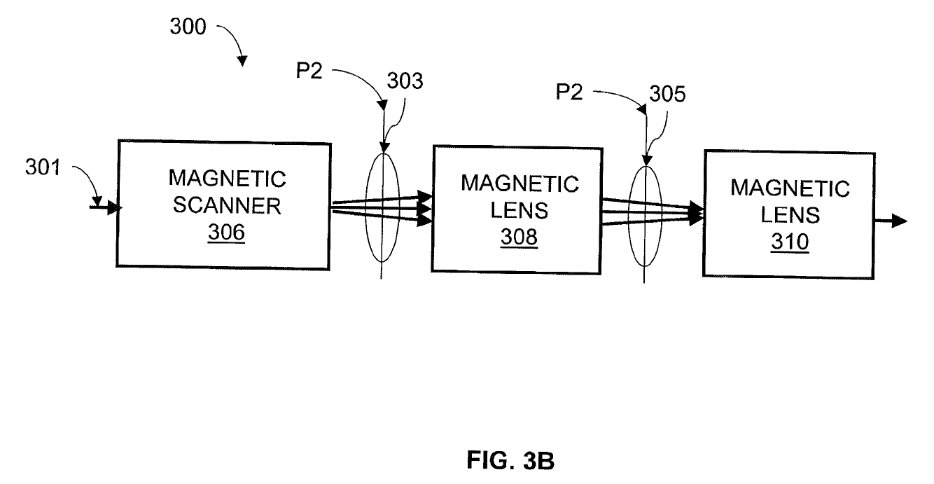

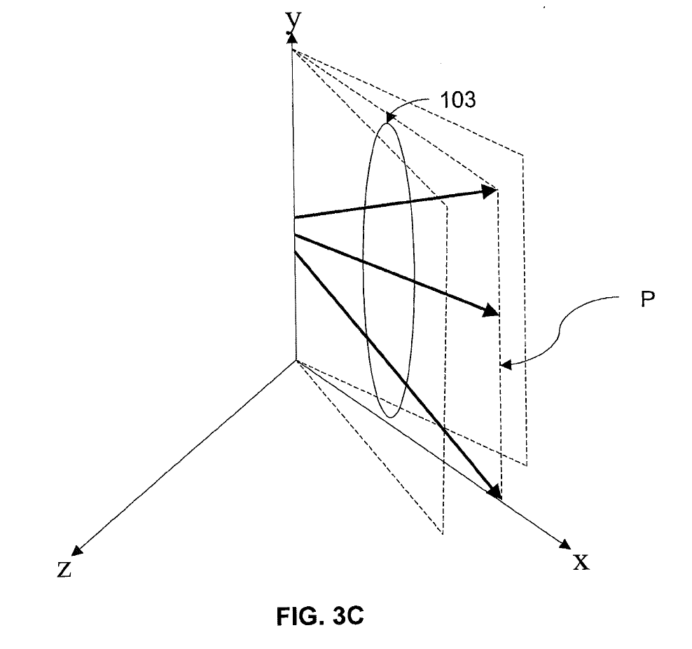

Ion Implanter System—FIGS. 3A, 3B, and 3C

There will now be shown and described in the context of FIGS. 3A, 3B, and 3C various instrumentalities and embodiments that may be used according to the principles of the invention. Those skilled in the art will appreciate variations from these examples that fall within the scope of the invention. For example, the various components described below can be combined in various ways to form multiple variations. As a result, the invention is not limited to the specific examples described below, but only by the claims and their equivalents. FIG. 3A illustrates one ion implanter system 300. Ion implanter system 300 includes ion source 302, analyzer 304, magnetic scanner 306, magnetic lens 308, magnetic lens 310, accelerator 312, and processor 318. Ion source 302 generates ion beam 301. Analyzer 304 receives ion beam 301 from ion source 302 and operates on ion beam 301 to select predetermined ions from ion beam 301. An example of analyzer 304 can be a momentum-analyzing magnet, such as a momentum-analyzing dipole magnet.

Magnetic scanner 306 scans ion beam 301 in diverging paths, such as paths 303. Magnetic scanner 306 operates on a single ion beam, such as ion beam 301, to create diverging paths 303 by the action of magnetic fields. An example of magnetic scanner 306 can be a dipole magnet having a controllable magnetic field that oscillates in a sawtooth fashion. Magnetic lens 308 receives ion beam 301 from paths 303 and amplifies the divergence of paths 303 to paths 305. Magnetic lens 308 also focuses ion beam 301 from paths 303 into a substantially single plane P, lying in the X-Y plane as shown in FIG. 3C. Magnetic lens 310 decreases deflecting power requirements of magnetic scanner 306. An example of magnetic lens 308 can be a quadrupole magnet or any other magnet that produces a quadrupole magnetic field as explained below. Magnetic lens 310 receives ion beam 301 from paths 305 generated by magnetic lens 308. Magnetic lens 310 focuses diverging paths 305 of ion beam 301 into substantially collimated paths 307. Magnetic lens 310 can further focus parallel paths 307 of ion beam 301 into plane P. Magnetic lens 310 can be a quadrupole magnet or any other magnet that produces a quadrupole magnetic field as explained below. Processor 318 is connected to magnetic lens 308 and magnetic lens 310. Processor 318 uses program instructions to control the magnetic fields of magnetic lens 308 and magnetic lens 310, according to user-identified or sensed process parameters.

Accelerator 312 receives ion beam 301 from collimated paths 307. Accelerator 312 accelerates ions from ion beam 301 to a target, not shown, for implanting ions into the target.

Vacuum chamber 314 forms vacuum V that is used to transport ion beam 301 from ion source 302 through accelerator 312. Those skilled in the art will appreciate various configurations of vacuum chamber 314. As vacuum V is not a perfect vacuum, ion beam 301 ionizes other gases in vacuum V. Positive ions are produced and are repulsed by ion beam 301. Electrons form charged cloud 316 that surrounds ion beam 301, but the electrons do not combine with particles of ion beam 301. Charged cloud 316 tends to neutralize ion beam 301.

Magnetic scanner 306 scans ion beam 301 using a magnetic field to create paths 303 from scanned ion beam 301. The divergence, or scan angle, of paths 303 from magnetic scanner 306 is typically smaller than a divergence created from an electric scanner. However, paths 303 are substantially focused in plane P. Divergence of paths 303 is increased by means of a beam amplifier. An example of a beam amplifier could be magnetic lens 308. Divergence is a deviation from an original path of an ion beam, such as that of paths 303 for ion beam 301. A scan angle is an amount of divergence from the center path 320 in any direction within plane P. Center path 320 represents the original trajectory of ion beam 310. Single plane P is a plane in which paths 303, 305, and 307 substantially lie.

Electric scanners drive neutralizing electrons out of an ion beam, which causes ions to repel each other and the ion beam to “blow up”. An increase in ions in the ion beam increases a repulsion of the ions such that ion beam current is limited. Repulsion of the ions is more severe if energy of the ions is lowered due to a decreased velocity of the ions. A larger wafer requires an increased ion beam current. Furthermore, in practice, ion implantation depths into wafers are being reduced. Reduced ion implantation depths require lower energy ion beams. Increased ion beam currents and reduced energy ion beams make magnetic scanners advantageous over electric scanners.

Other advantages of introducing a beam amplifier, such as magnetic lens 308, include a reduction of power required to drive magnetic scanner 306. Another advantage of the beam amplifier includes a focusing of the ion beam in the axis perpendicular to scan plane P. The beam amplifier also reduces power consumption of the system. The reduction of power consumption, therefore, reduces a cost of owning and operating ion implanter system 300.

FIG. 3B illustrates an overhead view of ion beam 301 of ion implanter system 300. The overhead view of ion implanter system 300 shows a convergence from paths 303 into the single plane P such as paths 305. The overhead view lies in plane P2, which is perpendicular to plane P discussed above. In addition to amplifying the divergence of paths 303 in plane P, magnetic lens 308 focuses ion beam 301 from paths 303 into plane P shown by paths 305.

FIG. 3C illustrates a three-dimensional view of paths 305 from ion beam 301 after being scanned by magnetic scanner 306 and amplified by magnetic lens 308. The three-dimensional view shows intentional divergence of paths 305 from ion beam 301 in the X-Y plane. The three-dimensional view shows no unintentional divergence of paths 305 in other planes.

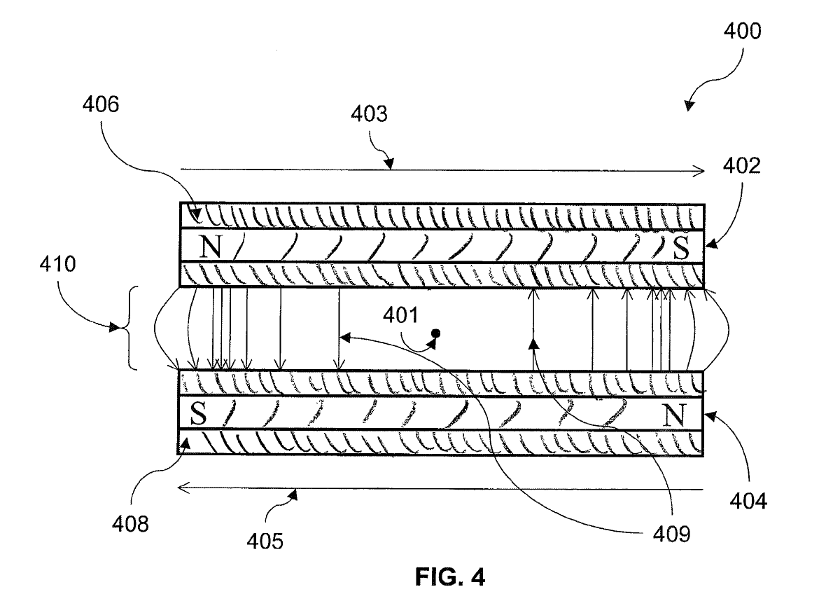

Magnetic Lens—FIGS. 4-6

FIG. 4 illustrates magnetic lens 400. Magnetic lens 400 includes a quadrupole magnet formed from two dipole magnets, 402 and 404. Dipole magnet 402 has a north pole labeled as “N” and a south pole labeled as “S”. Dipole magnet 404 also has a north pole labeled as “N” and a south pole labeled as “S”. Dipole magnet 402 has the north pole aligned with the south pole of dipole magnet 404. Dipole magnet 402 produces magnetization vector 403 that is aligned in an opposite direction with respect to magnetization vector 405 produced by dipole magnet 404. As aligned, dipole magnets 402 and 404 create a quadrupole magnetic field.

Dipole magnet 402 is formed from a ferromagnetic plate. Coil 406 is wound on dipole magnet 402. Dipole magnet 404 is also formed from a ferromagnetic plate. Coil 408 is wound on dipole magnet 404. Gap 410 separates dipole magnet 402 from dipole magnet 404. Electrical current passing through coils 406 and 408 produces a magnetic field with directions indicated by the open-ended arrows 409 within gap 410.

Point 401 located at the center of the magnetic lens 400 represents a point of zero magnetic field by symmetry. The magnetic field in the direction of magnetization vectors 403 or 405 increases linearly with distance from point 401. The magnetic field as indicated by the open-ended arrows within gap 410 is a quadrupole magnetic field that varies increasingly from point 401. Magnetic lens 400 is optionally programmable to vary the magnetic field within magnetic lens 400. For example, magnetic lens 400 can have a coil through which electric current flows. A micro controller or processor, such as processor 318 discussed above, can be programmed to determine an amount of current to flow through the coil. The amount of current and, therefore, the magnetic field of magnetic lens 400, can be dynamically controlled.

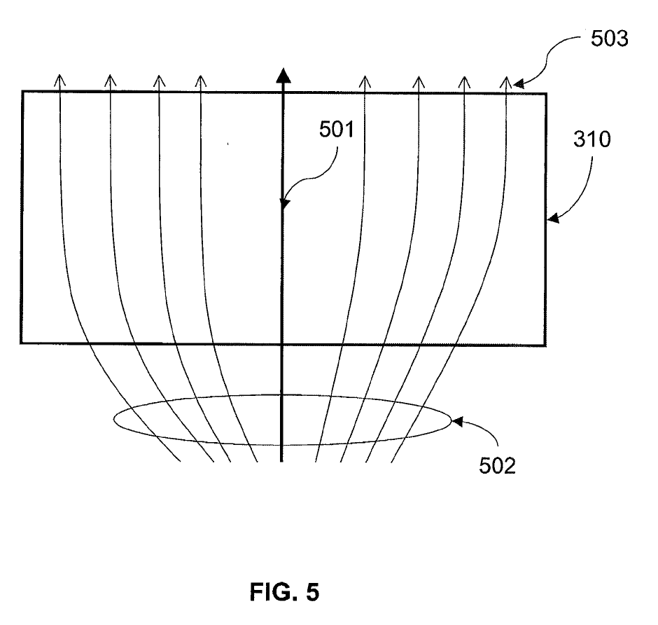

FIG. 5 illustrates one operation of magnetic lens 310. Arrow 501 lies in plane P, as discussed above, and indicates a direction in which an ion beam propagates in plane P, such as center path 320 discussed above. Diverging lines 502 indicate different paths of the scanned ion beam as described above. In some embodiments, the scanned ion beam is received from a beam amplifier such as beam amplifier 204 or magnetic lens 308. As the scanned ion beam enters magnetic lens 310, particles of the ion beam are deflected by a magnetic field produced by magnetic lens 310. The predetermined strength of the magnetic field causes paths 502 of the scanned ion beam to alter course into substantially collimated paths 503. The action of magnetic lens 310 reduces or eliminates the deviation from parallel because of the field effects within a gap of magnetic lens 310 that force the ion particles towards parallel paths 503 of travel. In some embodiments, the individual particles in ion beam travel in directions that deviate by no more than 0.3° from parallel. The substantially parallel paths 503 produced by magnetic lens 310 allow for a substantially constant angle of implantation of the ion beam into a tilted target. A substantially constant angle of implantation is useful as the implantation of ions becomes more uniform.

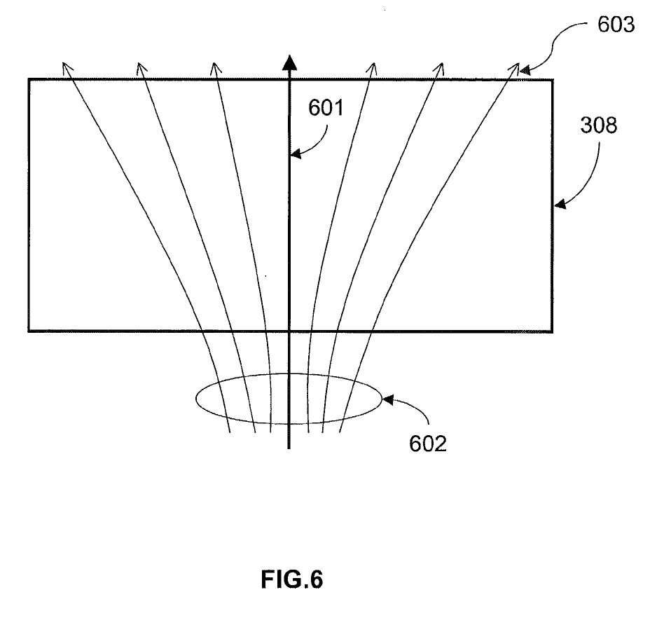

FIG. 6 illustrates the operation of magnetic lens 308. Arrow 601 lies in plane P, as discussed above, and indicates a direction in which an ion beam propagates in plane P, such as center path 320 discussed above. Diverging lines 602 indicate different paths of a scanned ion beam as described above. In some embodiments, the scanned ion beam is received from a scanner such as magnetic scanner 306. As the scanned ion beam enters magnetic lens 308, particles of the ion beam are deflected by a magnetic field produced by magnetic lens 308. The predetermined strength of the magnetic field causes paths 602 to alter course into paths 603 in which an angle of divergence is amplified. In some embodiments, magnetic lens 308 is programmable to vary the magnetic field within magnetic lens 308, which in turn varies of the angle of divergence. The amplified divergence of paths 603 produced by magnetic lens 308 allows for an increase in a scan angle of the ion beam from a scanner, as shown by paths 603. The increase in the scan angle allows for ion implantation into larger targets. An example of an application would be low energy ion implantation with high beam currents into twelve-inch wafers. The divergence of paths 603 is related to the magnetic field of magnetic lens 308. Accordingly, magnetic lens 308 differs from magnetic lens 310 by a manner in which magnetic lens 308 causes divergence of ion beam 310.

Advantages of the above embodiments include reducing a size of a magnet within a magnetic scanner, which reduces a size and a cost of the magnetic scanner. Other advantages include an improved beam divergence to provide a single plane beam. Other advantages include improved ion implantation into the target. Still, other advantages include creating large programmable scan angles of deflection paths for ion implantation. And still other advantages include introducing a divergence angle amplifier that greatly reduces the power required to drive the magnetic scanner.

Those skilled in the art are familiar with magnetic scanners, quadrupole magnets, analyzers, accelerators, and ion sources. Those skilled in the art will appreciate variations of the above-described embodiments that fall within the scope of the invention. As a result, the invention is not limited to the specific examples and illustrations discussed above, but only by the following claims and their equivalents.

We claim:

1. A system for amplifying a scan of an ion beam, comprising:
a magnetic scanner configured to scan the ion beam in a single plane; and
a beam amplifier configured to receive the ion beam from the magnetic scanner and amplify a divergence of the ion beam.

2. The system of claim 1, further comprising a magnetic lens configured to receive the ion beam from the beam amplifier and focus the ion beam into substantially collimated paths before impinging a tilted target.

3. The system of claim 2, wherein the magnetic lens includes a quadrupole magnet.

4. The system of claim 2, wherein the magnetic lens focuses the ion beam into the single plane.

5. The system of claim 2, wherein the magnetic lens is programmable to vary a magnetic field within the magnetic lens.

6. The system of claim 1, further comprising an analyzer configured to select predetermined ions from the ion beam.

7. The system of claim 6, wherein the analyzer includes a momentum-analyzing magnet.

8. The system of claim 7, wherein the momentum-analyzing magnet includes a dipole magnet.

9. The system of claim 1, further comprising an ion source configured to generate the ion beam.

10. The system of claim 1, further comprising a vacuum chamber configured to form a vacuum about the ion beam.

11. The system of claim 1, further comprising an accelerator configured to accelerate ions from the ion beam to a target.

12. The system of claim 1, wherein the beam amplifier comprises a magnetic lens configured to amplify the divergence of the ion beam and focus the ion beam in the single plane.

13. The system of claim 12, wherein the magnetic lens is programmable to vary a magnetic field within the magnetic lens.

14. The system of claim 12, wherein the magnetic lens comprises a quadrupole magnet.

15. A method of amplifying a scan of an ion beam, comprising:
scanning the ion beam with a magnetic field in a single plane; and
amplifying a divergence of the ion beam in the single plane.

16. The method of claim 15, further comprising generating the ion beam.

17. The method of claim 15, further comprising selecting predetermined ions from the ion beam.

18. The method of claim 15, further comprising focusing the ion beam in the single plane while amplifying the divergence of the ion beam.

19. The method of claim 15, further comprising focusing the ion beam in the single plane after amplifying the divergence of the ion beam.

20. The method of claim 19, wherein focusing the ion beam after amplifying includes creating a substantially collimated ion beam to a target.

21. The method of claim 19, wherein focusing the ion beam after amplifying is programmable by varying a magnetic field.

22. The method of claim 15, further comprising accelerating ions from the ion beam to a target.

23. The method of claim 15, wherein amplifying the divergence of the ion beam is programmable by varying a magnetic field.
